(19) United States
(12) Patent Application Publication
(10) Pub. No.: US 2025/0336642 A1
(43) Pub. Date: Oct. 30, 2025

(54) ENERGY ACCURACY FOR AN RF LINEAR ACCELERATOR ION IMPLANTATION SYSTEM

(71) Applicant: Axcelis Technologies, Inc., Beverly, MA (US)

(72) Inventor: Shu Satoh, Byfield, MA (US)

(21) Appl. No.: 19/192,403

(22) Filed: Apr. 29, 2025

Related U.S. Application Data
(60) Provisional application No. 63/640,408, filed on Apr. 30, 2024.

(51) Int. Cl. H01J 37/317; H01J 37/304

(52) U.S. Cl. CPC H01J 37/3171; H01J 37/304; H01J 2237/0473; H01J 2237/057; H01J 2237/20214; H01J 2237/20221; H01J 2237/24528

(57) ABSTRACT

An ion implantation system has an ion source configured to form an ion beam along a beam path. An accelerator is downstream of the ion source and configured to accelerate the ion beam to a predetermined energy. An energy filter is downstream of the accelerator and has an entrance configured to accept the ion beam. A beam measurement device can be positioned downstream of the accelerator along the beam path and is configured to determine an angular orientation of the ion beam. A controller further controls one or more of the accelerator and final energy filter based on the angular orientation of the ion beam with respect to the entrance of the energy filter. The controller can control beam parameters of an energy filter formula based on the angular orientation of the ion beam, where the energy filter formula is based on a characterization of the energy filter.

### REFERENCE TO RELATED APPLICATIONS

This application claims the benefit of U.S. Provisional Application Ser. No. 63/640,408 filed Apr. 30, 2024 entitled, “IMPROVED ENERGY ACCURACY FOR AN RF LINEAR ACCELERATOR ION IMPLANTATION SYSTEM”, the contents of which are herein incorporated by reference in their entirety.

### FIELD OF THE INVENTION

The present invention relates generally to ion implantation systems, and more specifically to a system and method utilizing a device for measuring a beam angle to provide accurate energies to a final energy filter in an ion implantation apparatus.

### BACKGROUND OF THE INVENTION

In the manufacture of semiconductor devices, ion implantation is used to dope semiconductors with impurities. Ion implantation systems are often utilized to dope a workpiece, such as a semiconductor wafer, with ions from an ion beam, in order to either produce n- or p-type material doping, or to form passivation layers during fabrication of an integrated circuit. Such beam treatment is often used to selectively implant the wafers with impurities of a specified dopant material, at a predetermined energy level, and in controlled concentration, to produce a semiconductor material during fabrication of an integrated circuit. When used for doping semiconductor wafers, the ion implantation system injects a selected ion species into the workpiece to produce the desired extrinsic material. Implanting ions generated from source materials such as antimony, arsenic, or phosphorus, for example, results in an “n-type”extrinsic material wafer, whereas a “p-type” extrinsic material wafer often results from ions generated with source materials such as boron, gallium, or indium.

A typical ion implanter includes an ion source, an ion extraction device, a mass analysis device, an acceleration (or deceleration) stage when the desired ion energy differs from the extraction energy, a beam transport device and a wafer processing device. The ion source generates ions of desired atomic or molecular dopant species. These ions are extracted from the source by an extraction system, typically a set of electrodes, which energize and direct the flow of ions from the source, forming an ion beam. Desired ions are separated from the ion beam in a mass analysis device, typically a magnetic dipole performing mass dispersion or separation of the extracted ion beam, whereby the ions are accelerated or decelerated to a desired final energy through an accelerator (or a decelerator). The beam transport device, typically a vacuum system containing a series of focusing devices, transports the ion beam to the wafer processing device while maintaining desired properties of the ion beam. Finally, semiconductor wafers are transferred into and out of the wafer processing device via a wafer handling system, which may include one or more robotic arms, for placing a wafer to be treated in front of the ion beam and removing treated wafers from the ion implanter.

### SUMMARY OF THE INVENTION

The following presents a simplified summary of the invention in order to provide a basic understanding of some aspects of the invention. This summary is not an extensive overview of the invention. It is intended neither to identify key or critical elements of the invention nor to delineate the scope of the invention. Rather, its primary purpose is merely to present one or more concepts of the invention in a simplified form as a prelude to the more detailed description that is presented later.

In accordance with one example aspect of the disclosure, an ion implantation system comprises an ion source configured to form an ion beam along a beam path. An accelerator, such as an RF linear accelerator, is positioned downstream of the ion source and is configured to accelerate the ion beam to a predetermined energy. An energy filter is further positioned downstream of the accelerator and is configured to accept the ion beam at an entrance thereof. A beam measurement device is further selectively positioned downstream of the accelerator along the beam path and configured to determine an angular orientation of the ion beam. The beam measurement device can be selectively positioned between the accelerator and the energy filter along the beam path, such as along an exit axis of the accelerator. A controller, for example, is further provided and configured to control one or more of the accelerator and the final energy filter based on the angular orientation of the ion beam with respect to the entrance of the energy filter.

In one example, the beam measurement device can be configured to translate and/or rotate with respect to the beam path to determine the angular orientation of the ion beam with respect to the entrance of the energy filter. The energy filter, for example, can define the beam path as being one of a reference beam path passing through the energy filter and an unfiltered beam path not passing through the energy filter. In one example, the controller is configured to define the beam path by selectively energizing the energy filter. The beam measurement device, for example, can be positioned along the unfiltered beam path downstream of the accelerator, whereby the angular orientation of the ion beam with respect to the entrance of the energy filter can be determined by the beam measurement device when the energy filter is not energized.

The beam measurement device, for example, can comprise a mask positioned upstream of a faraday, wherein a plurality of slits are defined in the mask. The beam measurement device can be thus configured to determine an angular offset of the ion beam as the ion beam enters the energy filter based on measurements attained from the faraday downstream of the plurality of slits. The mask can comprise a plurality of tines generally defining the plurality of slits, wherein the plurality of slits have a slit length, and wherein the plurality of tines are separated from one another by a slit width.

The controller, for example, can be configured to control the accelerator based on the angular orientation of the ion beam to obtain a beam angle of approximately zero at the entrance of the energy filter. In another example, the controller is further configured to control one or more beam parameters of an energy filter formula based on the angular orientation of the ion beam, wherein the energy filter formula is based on a characterization of the energy filter.

In another example aspect, an ion implantation system is provided comprising an ion source configured to form an ion beam along a beam path. An accelerator is positioned downstream of the ion source and configured to accelerate the ion beam to a predetermined energy. An energy filter comprising positioned downstream of the accelerator and configured to accept the ion beam at an entrance of the energy filter. A beam measurement device is selectively positioned downstream of the accelerator along the beam path, wherein the beam measurement device is configured to determine an angular orientation of the ion beam with respect to the entrance of the energy filter based, at least in part, on a position of the beam measurement device with respect to the beam path. Further, a controller is configured to control one or more of the accelerator and energy filter based on the angular orientation of the ion beam determined by the beam measurement device.

The energy filter can comprise a magnetic energy filter or an electrostatic energy filter. The beam measurement device can be provided between the entrance of the energy filter and an exit axis of the accelerator, and the beam measurement device can be configured to determine an angular offset of the ion beam as the ion beam enters the energy filter. In another example, the energy filter can comprise an electromagnet configured to selectively define the beam path as one of a reference beam path passing through the energy filter or an unfiltered beam path not passing through the energy filter based on a selective energizing of the energy filter.

The controller can be configured to control the accelerator based on the angular orientation of the ion beam, thereby defining a beam angle of approximately zero at the entrance of the energy filter. The controller can be further configured to control one or more beam parameters of an energy filter formula based on the angular orientation of the ion beam, wherein the energy filter formula is based on a characterization of the energy filter.

In accordance with another example aspect of the disclosure, an implantation system is provided, wherein an ion source is configured to form an ion beam along a beam path. An RF linear accelerator is positioned downstream of the ion source and is configured to accelerate the ion beam to a predetermined energy along an exit axis of the RF linear accelerator. A magnetic energy filter, for example, is positioned downstream of the RF linear accelerator and configured to accept the ion beam at an entrance of the magnetic energy filter. A beam measurement device, for example, is selectively positioned downstream of the RF linear accelerator along the beam path, wherein the beam measurement device comprises a mask positioned upstream of a faraday and is configured to determine an angular orientation of the ion beam with respect to the entrance of the magnetic energy filter based, at least in part, on current of the ion beam passing through the mask and reaching the faraday. The angular orientation of the ion beam with respect to the entrance of the magnetic energy filter can be further based a position of the beam measurement device with respect to the beam path. A controller is further configured to control one or more beam parameters associated with the RF linear accelerator and magnetic energy filter based on the angular orientation of the ion beam, wherein the one or more beam parameters are further associated with an energy filter formula and a characterization of the magnetic energy filter.

Thus, to the accomplishment of the foregoing and related ends, the following description and annexed drawings set forth in detail certain illustrative aspects and implementations of the invention. These are indicative of but a few of the various ways in which one or more aspects of the present invention may be employed. Other aspects, advantages and novel features of the invention will become apparent from the following detailed description of the invention when considered in conjunction with the annexed drawings.

### BRIEF DESCRIPTION OF THE DRAWINGS

FIG. 1A is a schematic representation of an ion implantation system illustrating various example aspects of the present disclosure.

FIG. 1B is a schematic representation of an ion implantation system illustrating several example aspects of the present disclosure.

FIG. 2 is a schematic diagram showing various parameters associated with a behavior of an ion beam entering an energy filter.

FIG. 3 is a schematic representation of a beam angle measurement apparatus in accordance with various examples of the present disclosure.

FIGS. 4A-4B are schematic representations of a determination of deviance in ion beam angle by a beam angle measurement system in accordance with various examples of the present disclosure.

FIG. 5 is a method for determining an angle of an ion beam according to one or more aspects of the present invention.

### DETAILED DESCRIPTION OF THE INVENTION

One or more aspects of the present invention are described with reference to the drawings, wherein like reference numerals are generally utilized to refer to like elements throughout, and wherein the various structures are not necessarily drawn to scale. In the following description, for purposes of explanation, numerous specific details are set forth in order to provide a thorough understanding of one or more aspects of the present invention. It may be evident, however, to one skilled in the art that one or more aspects of the present invention may be practiced with a lesser degree of these specific details. In other instances, well-known structures and devices are shown in block diagram form in order to facilitate describing one or more aspects of the present invention.

It is desirable to provide precision in a final energy of ions implanted into a workpiece for most semiconductor ion implantation processing, as the final energy determines a depth of a penetration of the ions into the semiconductor workpiece, thereby affecting the characteristic of the final semiconductor products. Most ion implanters are equipped with an accelerator or decelerator stage, whereby the accuracy of the final energy is generally determined by the accuracy of the accelerator or decelerator stage.

In a DC-based accelerator, for example, determining the final energy is rather straightforward, as a DC potential of the accelerator can be readily measured with an appropriate voltmeter, such as a voltmeter having a high precision resistive voltage divider. In an RF-based accelerator, however, determination of the final energy is more complex. For example, the RF-based accelerator can comprise multiple RF acceleration stages, whereby each RF acceleration stage is configured to accelerate ions via a time varying voltage at a high frequency. Even if the peak voltage of each RF acceleration stage is known, ions achieve a different energy depending on the phase of RF voltage as the ions pass through the respective stages. Due to such complexities in RF acceleration, instead of determining the final energy directly from the voltage and timing of each acceleration stage, an energy filter (e.g., a magnetic filter or electrostatic energy filter) is positioned downstream of the last RF acceleration stage, and parameters of the RF accelerator are tuned to maximize the transmission through the energy filter, such that the energy filter is configured to pass only narrow band of energetic ions around the desired energy.

An energy filter is a device in which the position of an outbound ion beam that is output from the energy filter depends on a difference in energy (e.g., referred to as energy dispersive) of the inbound ion beam entering the energy filter. Further, when dispersed by energy, a narrow slit positioned downstream of the and the energy at which energy filter is set. An energy filter can filter out most energies of the outbound ion beam, except for a narrow band around the desired final energy. The energy filter, for example, can comprise a dipole magnet or an electrostatic deflector. Providing an energy filter comprising a dipole magnet, however, is advantageous due to having no significant high voltage breakdown. An energy filter based on a dipole magnet, for example, is dispersive on momentum of an ion (e.g., a product of a mass of the ion and velocity), but it can also be considered energy dispersive, since the mass of the ion reaching the energy filter is known from mass analysis performed after extraction from the ion source. It is noted that while the present disclosure provides various examples of the energy filter comprising a dipole magnet, it is also to be appreciated that the disclosure contemplates the energy filter as alternatively comprising an electrostatic deflector, which is purely energy dispersive, as will be appreciated by one of ordinary skill in the art.

In an ideal example, the position of the outbound ion beam from the energy filter will depend only on the energy of ion beam, whereby the energy of ion beam solely defines the position of the outbound ion beam as it emerges from the energy filter. However, in practice in a commercial RF-based accelerator, the position of the outbound ion beam is also affected by the angle at which the inbound ion beam enters the energy filter, known as a beam entrance angle of the inbound ion beam. In normal operation of an RF accelerator, variability of the beam entrance angle is normally quite limited, thus leading to only a minor ambiguity in the determination of the final energy of the ion beam. However, with the recent demand for a more accurate determination of the final energy of the ion beam, it is desirable to resolve even such a minor ambiguity in the final energy of the ion beam caused by the beam entrance angle. While energy filter designs have been previously proposed attempting to eliminate the dependence on beam entrance angle, such designs have required a substantially large increase in a size and length of the energy filter, and have thus been considered to be undesirable and non-practical.

In RF-based accelerators and DC-based accelerators, for example, ions can be repeatedly accelerated through multiple acceleration stages of an accelerator. For example, a typical RF accelerator comprises a plurality of lenses (e.g., ten or more quadrupole lenses), as well as a plurality of voltage-driven RF acceleration gaps, which can also act as lenses. Each of the plurality of lenses can alter a trajectory of the ion beam exiting the RF accelerator, such that the accelerated ion beam can be offset from a reference beam path. If the accelerated ion beam is then transported into the energy filter, such as an energy analyzer magnet, to refine the energy of the ion beam at such an angular offset, the energy of the accelerated ion beam passed through the energy analyzer magnet will differ from an expected energy of a desired or ion beam for which the energy analyzer magnet may have been previously calibrated. Such an uncertainty of the angle of the accelerated ion beam entering the energy analyzer magnet can be a significant source of the energy uncertainty for the ion implanter.

As the demand for more precise knowledge of the final energy of the ion beam increases, knowing the ion beam entrance angle has become more important, either to tune the ion beam to have a zero (perpendicular) entrance angle, or by applying a correction to a calibration of the energy filter to compensate for the non-zero angle. The present disclosure is thus directed toward a measuring system for determining the entrance angle of the ion beam as it enters the energy filter. As such, the present disclosure provides suitable systems and methods for yielding accurate final beam energies in various ion implantation systems.

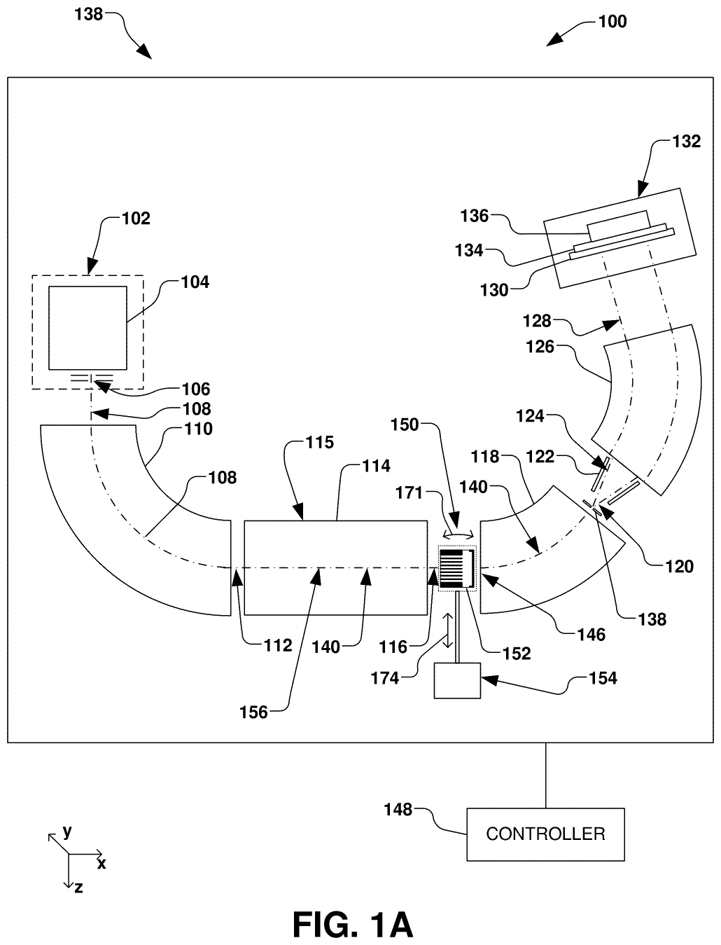

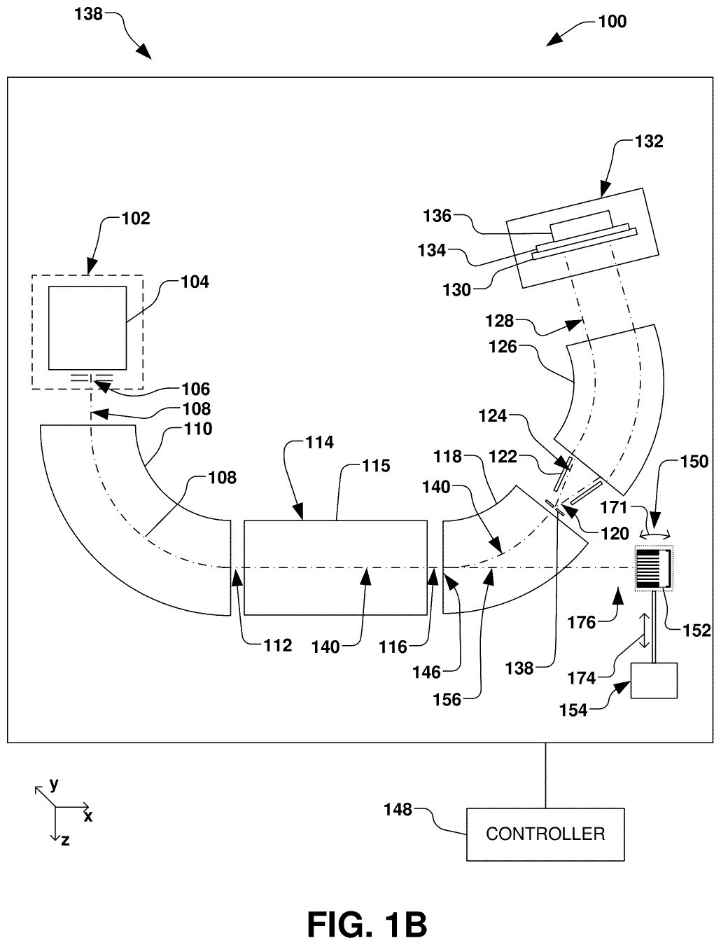

Referring now to the figures, FIGS. 1A-1B illustrate an ion implantation system 100 in accordance with various example aspects of the present disclosure. The ion implantation system 100 of FIGS. 1A-1B, for example, comprises an ion source 102, which comprises an ion source chamber 104 configured to generate ions of a predetermined species, as well as an extraction electrode 106 configured to extract the generated ions from the ion source chamber and to accelerate the ions to an intermediate energy, thereby generally forming an ion beam 108. A mass analyzer 110, for example, removes unwanted ion mass and charge species from the ion beam 108 to define a mass analyzed ion beam 112 comprised of ions of known mass and charge state. An accelerator 114, for example, is positioned downstream of the mass analyzer 110 and configured to accelerate the mass analyzed ion beam 112 to produce an accelerated ion beam 116. In accordance with one example of the present disclosure, the accelerator 114, for example, comprises an RF linear accelerator 115 (also referred to as an RF LINAC) in which ions are accelerated repeatedly by an RF field. Alternatively, the accelerator 114 comprises a DC accelerator (e.g., a tandem electrostatic accelerator), in which ions are accelerated with a stationary DC high voltage.

The ion implantation system 100 illustrated in FIGS. 1A-1B, for example, is also referred to as a post-acceleration implanter, as the accelerator 114 is positioned downstream of the mass analyzer 110. An energy filter 118 (e.g., a magnetic or electrostatic energy analyzer), for example, is positioned downstream of the accelerator 114, wherein the energy filter is configured to remove unwanted energy spectrum from the accelerated ion beam 116 emerging from the accelerator 114, whereby the energy filter generally defines a final energy ion beam 120. A beam scanner 122, for example, is configured to scan the final energy ion beam 120, whereby the final energy ion beam is scanned back and forth at a predetermined frequency (also called a “fast scan”) to define a scanned ion beam 124. The beam scanner 122, for example, is configured to electrostatically or electromagnetically scan the final energy ion beam 120 to define the scanned ion beam 124.

The scanned ion beam 124, for example, is further passed into an angle corrector lens 126, such as a magnetic point-to-parallel lens, wherein the fanning out of the final energy ion beam 120 caused by the beam scanner 122 is converted to a final ion beam 128 (e.g., a parallel and side-shifted ion beam). The final ion beam 128, for example, is subsequently implanted into a workpiece 130 (e.g., a semiconductor wafer) that can be selectively positioned in a process chamber or end station 132. For example, an electrostatic chuck (ESC) 134 is provided on a mechanical scanning apparatus 136, wherein the ESC is configured to support the workpiece 130, and wherein the mechanical scanning apparatus is configured to selectively translate the ESC and the workpiece through the final ion beam 128. The workpiece 130, for example, can be moved generally orthogonal to the final ion beam 128 (e.g., illustrated moving in and out of the paper) via the mechanical scanning apparatus 136 in a hybrid scan scheme to irradiate the entire surface of the workpiece 130 uniformly. It is noted that the present disclosure appreciates various other mechanisms and methods for scanning the ion beam 108 and/or the final ion beam 128 in one or more directions, and all such mechanisms and methods are contemplated as falling within the scope of the present disclosure.

The ion implantation system 100 of FIGS. 1A-1B, for example, is configured as a hybrid parallel-scan single-workpiece ion implantation system in which the ion beam 108 is scanned in a first direction (e.g., horizontally or in the x-direction) and the workpiece 130 is translated in a second direction orthogonal to the first direction (e.g., vertically or in the y-direction).

In utilizing the RF LINAC 115 to accelerate the ion beam 108, a final energy of the final ion beam 128 provided to the workpiece 130 is based on a complex function of a plurality of factors, such as multiple resonator voltages and phase settings associated with the RF LINAC for a desired implant species and desired energy of implantation. As such, the final energy of the final ion beam 128 is defined as a pass band setting of the energy filter 118 receiving the accelerated ion beam 116 from the output of the RF LINAC 115, whereby the resonator settings are fine-tuned to adequately pass the desired energy through the energy filter.

The present disclosure appreciates that it can be advantageous to understand the filtering characteristics and/or limitations of the energy filter 118 in order to define the accuracy of the final energy of the final ion beam 128. In simple terms, the present invention appreciates that energy filtering characteristics of the energy filter 118, for example, can be compared to a simple optical prism (e.g., a simple optical spectrometer) in which the difference in the refractive index on wavelength of light is used to disperse a broad spectrum light into a spectrum of dispersed light at different positions according to wavelength, and by placing a slit in the spectrum of dispersed light, one can extract a monochromatic light ray. For the energy filter 118, an ion beam emitted from the energy filter is dispersed according to the energy of the ion beam, and a desired energy can be based on a position or location of an energy resolving slit (ERS) 138 through which the final energy ion beam 120 passes.

The present disclosure appreciates that as a refractive index of the optical prism can be adjusted to select a particular color of light passed through the slit, so too can a field of the energy filter 118 (e.g., a magnetic field in a magnetic energy filter or an electric field on electrostatic energy filter) be controlled to select a particular energy output from the energy filter through the ERS 138. The comparison of an optical prism to the RF LINAC 115 also illustrates the difficulty encountered in energy variation in systems employing RF LINACs. For example, if the broad-spectrum white light enters the optical prism slightly off-axis, although the prism is unchanged, the prism will transmit a different color of light through the optical slit. On the energy filter 118, if the accelerated ion beam 116 enters the energy filter at an angle that differs from a designed entrance angle, the final energy ion beam 120 selected by the ERS 138 will be of a different energy.

While not shown in FIGS. 1A-1B, the present disclosure contemplates the RF LINAC 115, for example, as comprising a plurality of lenses (e.g., ten or more quadrupole lenses), as well as a plurality of RF acceleration gaps, which can also act as lenses. Each of the plurality of lenses, for example, can alter a trajectory of the accelerated ion beam 116 exiting the RF LINAC, such that the accelerated ion beam can be slightly off-axis, off-angle, or off-center from a reference beam path 140.

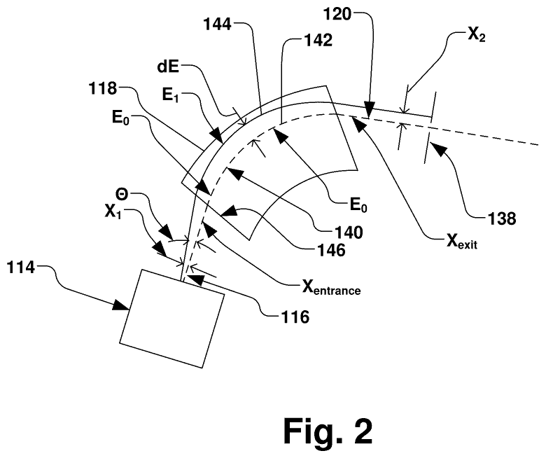

FIG. 2 illustrates a general nomenclature of beam parameters related to the reference beam path 140 as the accelerated ion beam 116 passes through the energy filter 118. In one example, the energy filter 118 can comprise a magnetic energy filter and is configured such that a reference ion beam 142 of a reference energy E₀ enters the energy filter on an entrance axis X_{entrance} and exits the energy filter on an exit axis Xₑₓᵢₜ. When an offset ion beam 144 of a divergent energy E₁ (e.g., the reference energy E₀ plus an energy offset dE) enters the energy filter 118 having an entrance lateral offset X₁ and entrance angle offset Θ from the entrance axis X_{entrance}, an exit lateral offset X₂ of the offset ion beam 144 at the ERS 138 can be generally written as a function of the entrance lateral offset X₁, the entrance angle offset Θ, and the energy offset dE as:

$${X}_{2} = ( {a}_{1} * {X}_{1} ) + ( {a}_{2} * Θ ) + ( {a}_{3} * dE ) , \qquad ( 1 )$$

where a₁, a₂, and as are respective coefficients that can be based on the design of the energy filter. Equation (1) is referred to as an “energy filter formula” that generally characterizes the energy filter 118. The beam parameters X₁, Θ, dE, and X₂ of equation (1) are “offset” values from the trajectory of the reference ion beam 142 of reference energy E₀ entering the energy filter 118 along the entrance axis X_{entrance} and exiting the energy filter along the exit axis Xₑₓᵢₜ and can be controlled by selectively varying the strength of the energy filter.

In the case of the energy filter 118 being an ideal energy filter, coefficients a₁ and a₂ are zero, yielding the exit lateral offset X₂, or the final beam position of the accelerated ion beam 116, to be a function of beam energy (e.g., the energy offset dE), alone. The present disclosure appreciates that providing the energy filter 118 having a₁=0 can be designed without significant additional complexity or increase in size. In one example, such as contemplated in an XE High Energy implanter manufactured by Axcelis Technologies of Beverly, MA, a magnetic energy analyzer (e.g., the energy filter 118) can have coefficients a₁=0, a_{2=0.93} mm/mrad and as =3.9 mm/%, whereby the energy filter formula of equation (1) yields:

$${X}_{2} ( mm ) = ( 0.93 * Θ ) ( m rad ) + ( 3.9 * dE ) ( \% ) . \qquad ( 2 )$$

Thus, in an example where the divergent energy E₁ of the offset ion beam 144 is offset by 3% from the reference energy E₀ (the energy offset dE=3%) entering the energy filter 118 on-axis (X₁=Θ=0), the accelerated ion beam 116 at the ERS 138 will have an exit lateral offset X₂=11.7 mm. Conversely, if the accelerated ion beam 116 at the ERS 138 is offset by the exit lateral offset X₂ of 11.7 mm, the energy offset dE can be determined to be 3%, assuming the entrance angle offset Θ=0. However, equation (2), for example, also provides that even if the accelerated ion beam 116 is at the center of the ERS 138 (e.g., X₂₌₀), there is still a possibility that the energy offset dE is non-zero (e.g., by perhaps 2%), if the entrance angle offset Θ from the center line of the entrance axis X_{entrance} is non-zero, such as when the entrance angle offset Θ=−8.39 mrad (e.g., approximately −0.48°). In order to precisely identify the beam energy of the accelerated ion beam 116, the disclosure presently appreciates that it is thus beneficial to understand the entrance angle offset Θ.

The present disclosure thus utilizes an understanding of the entrance angle offset Θ of the accelerated ion beam 116 entering into the energy filter 118 to provide improved precision in the identification of the beam energy of the accelerated ion beam passing through the ERS 138. Conventionally, such a correlation of the entrance angle offset Θ into an energy filter to the beam energy through an ERS has been ignored, or the entrance angle offset has been assumed to be zero, leaving a small, but finite, ambiguity in the actual beam energy.

Referring once again to FIGS. 1A and 1B, a controller 148, for example, is further provided and configured to provide control of one or more of the various features of the ion implantation system 100. The controller 148, for example, is configured to selectively control one or more of the ion source 102, mass analyzer 110, accelerator 114, energy filter 118, angle corrector lens 126, and mechanical scanning apparatus 136, and may comprise any number of processors, control panels, input devices, programmable logic, or other control mechanism known to one of skill in the art.

Thus, in accordance with one example of the present disclosure, a beam angle measurement (BAM) system 150 is selectively provided upstream of the entrance 146 of the energy filter 118, as illustrated in FIG. 1A, in order to determine the angle of the accelerated ion beam 116 as it enters the energy filter. For example, the BAM system 150 is configured to selectively position a beam measurement device 152 with respect to the accelerated ion beam 116. For example, the BAM system 150 comprises a positioning device 154 (e.g., one more actuators, motors, linkages, arms, or other motion apparatuses) configured to selectively translate and/or rotate the beam measurement device 152 through the reference beam path 140 of the accelerated ion beam 116, whereby beam measurement device can be positioned outside of the path of the accelerated ion beam when measurements are not being performed. For example, the positioning device 154 comprises one or more of a linear actuator and a rotary actuator configured to selectively position the beam measurement device 152 with respect to the accelerated ion beam 116.

Alternatively, the beam measurement device 152 can be located as an extension of the accelerator 114, as illustrated in FIG. 1B, such as when the energy filter 118 is a magnet (e.g., an electromagnet) or analyzer that allows such a passage of the accelerated ion beam to travel along an alternate beam path 156 (e.g., an unfiltered beam path) by simply turning off or deactivating the energy filter or analyzer. For example, the beam measurement device 152 can be positioned along the alternate beam path 156, whereby the accelerated ion beam 116 is not filtered by the energy filter 118. As such, instead of retracting the beam measurement device 152 out of the reference beam path 140 of the accelerated ion beam 116 as shown in FIG. 1A, the positioning of the beam measurement device of the BAM system 150 shown in FIG. 1B generally allows for the angle measurement to be made by turning the magnet of the energy filter 118 off, thus deactivating the energy filter and thereby allowing the accelerated ion beam 116 to travel straight into the beam measurement device 152 via the alternate beam path 156. It is noted that turning off the magnet of the energy filter 118 may incur a period of time for the magnetic field to adequately subside.

It is noted that the accelerated ion beam 116 consists of many beam particles, and each particle in the ion beam may have slightly different parameters, such as a position offset from centerline, an angle offset, and even slightly different energy. In discussing the energy of the ion beam, it is to be appreciated that the energy is an averaged, or mean, energy value for all of the beam particles in the ion beam. Further, it is to be appreciated that the relationship between the energy and entering angle on the energy analyzer is the mean value of beam angle over the entire ion beam going into the energy analyzer to be measured.

The BAM system 150, for example, is configured to measure a mean value of an angular distribution (e.g., Θ₁, Θ₂, etc.) over all the particles of the accelerated ion beam 116 emerging from the RF LINAC 115, as will be discussed in greater detail infra. As such, the angular distribution information can be used in adjusting, modifying, or correcting the beam angle in the accelerated ion beam 116, and the present disclosure also contemplates a correction to an energy calibration formula or energy filter formula that can be applied to attain the actual beam energy.

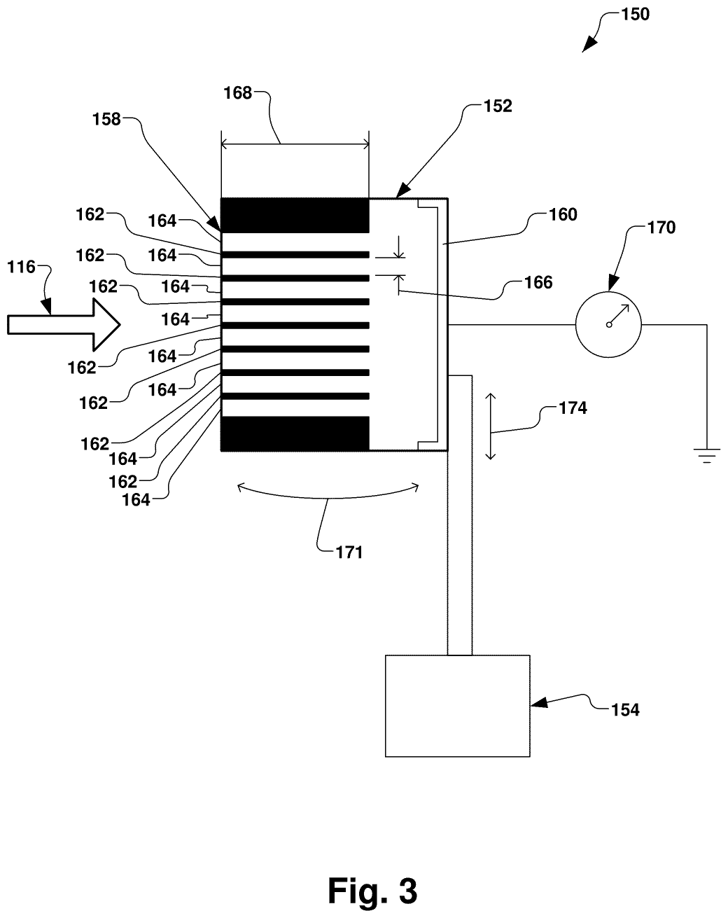

The present disclosure contemplates the BAM system 150 as comprising one or more features described in co-owned U.S. Pat. No. 7,361,914, by Rathmell et al., the contents of which are incorporated by reference herein, in its entirety. For example, in accordance with one example of the present disclosure, the BAM system 150 is illustrated in FIG. 3, wherein the beam measurement device 152 comprises a mask 158 (e.g., a comb-like structure) positioned upstream of a faraday 160 of the beam measurement device. The mask 158, for example, comprises a plurality of mask members 162 (e.g., a plurality of tines) generally defining a plurality of elongate narrow slits 164. The mask 158 of the beam measurement device 152 for example, may be formed out of graphite.

The plurality of elongate narrow slits 164 (also called channels), for example, are generally defined by a slit width 166 (e.g., a slit opening) and a slit length 168, both of which determine the angular resolution. The slit width 166 and slit length 168, as well as the number of elongate narrow slits 164, for example, can be selected based on a desired level of angular resolution of the beam measurement device 152. The present disclosure appreciates that the total number of the elongate narrow slits 164, the overall width of the mask 158, and depth (extending into the page—not shown) of the mask, for example, can be sized to be wide enough to cover the entire width and height of ion beam 116, whereby the measured angular distribution covers the entirety of the ion beam.

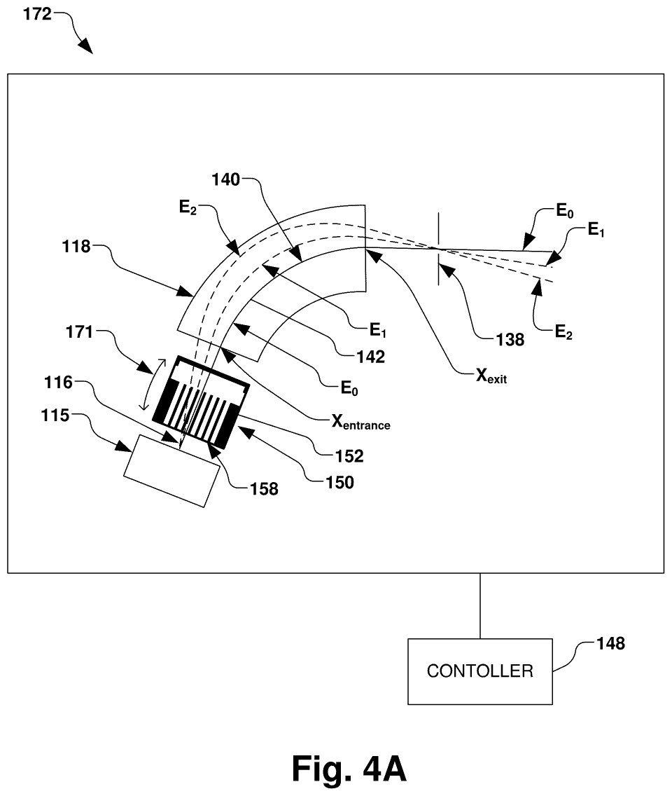

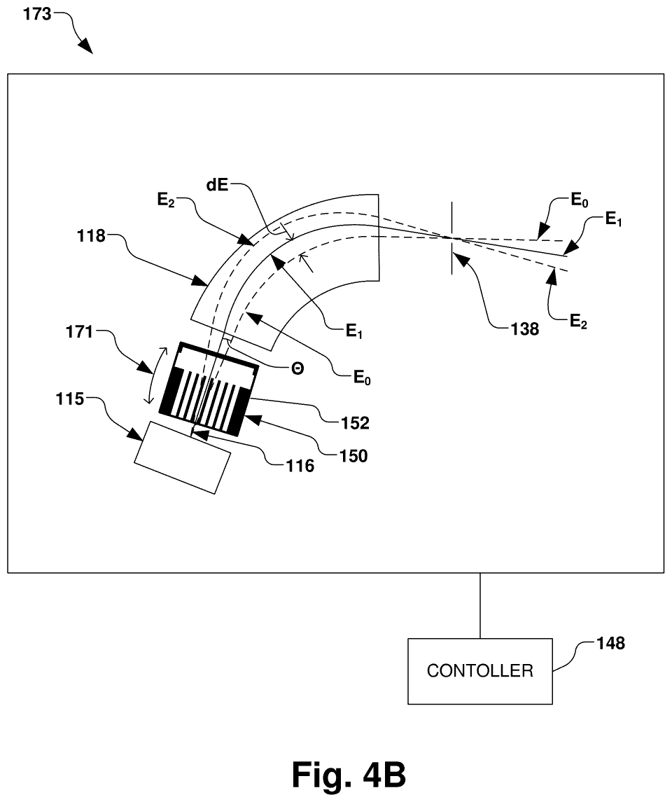

As such, a high angular resolution can be achieved by a high aspect ratio (e.g., the ratio between the slit width 166 and slit length 168 of the respective elongate narrow slits 164), of mask members 162, and thus, the plurality of elongate narrow slits 164, whereby the beam measurement device 152 can be configured to selectively pass the accelerated ion beam 116 through the plurality of elongate narrow slits and be measured by the faraday 160 of the beam current measurement device that is downstream of the plurality of mask members. A measurement 170 of the accelerated ion beam 116 passing through the plurality of elongate narrow slits 164, for example, is based on the configuration of the plurality of mask members discussed above, as well as on a rotation 171 (e.g., determined by an encoder of the positioning device 154) of the mask 158 of the beam measurement device 152 through the accelerated ion beam, as illustrated in FIGS. 4A-4B.

FIG. 4A illustrates a reference configuration 172 of the beam measurement device 152 when the reference ion beam 142 of reference energy E₀ enters the energy filter 118 on the entrance axis X_{entrance}, thus providing the entrance angle offset Θ equal to zero. The strength of energy filter 118, for example, can be controlled by the controller 148 such that the reference ion beam 142 exits the energy filter and passes through the ERS 138 (e.g., X₂₌₀ in equation (2)), whereby the entrance angle offset Θ being equal to zero can be confirmed by the beam measurement device 152, indicating maximum beam transmission through the mask 158 when Θ=0.

FIG. 4B illustrates an example configuration 173 whereby the accelerated ion beam 116 having any of the reference energy E₀ or the divergent energies E₁, E₂, the divergent energy E₁ can similarly pass through the ERS 138, satisfying the condition of the exit lateral offset X₂₌₀ in equation (2). However, the rotation 171 of the beam measurement device 152 can be further utilized to determine the entrance angle offset Θ and the energy offset (dE=E₁−E₀) required to satisfy the relationship given by the equations (1) or (2), above when dE is non-zero. As illustrated in FIG. 4B, the rotation 171 of the beam measurement device 152 can be utilized to determine the maximum beam transmission of the accelerated ion beam 116 to find the non-zero entrance angle offset Θ, indicating that the divergent energy E₁ of the accelerated ion beam differs from the reference beam energy E₀, or that the energy offset dE of equations (1) or (2) is non-zero. The entrance angle offset Θ obtained by the beam measurement device 152, for example, thus identifies that the beam energy of the accelerated ion beam 116 not only differs from the reference energy E₀, but also indicates the amount of the energy offset, thus facilitating further control of the various components of the ion implantation system 100 of FIG. 1.

The beam measurement device 152, for example, can be further configured to linearly translate (e.g., illustrated by arrow 174 in FIG. 3) whereby once the measurement is performed, the beam measurement device 152 is retracted such that the accelerated ion beam 116 can pass through the energy filter 118 of FIG. 1, unobstructed. Alternatively, a retractable motion could be avoided in the configuration shown in FIG. 1B, whereby the BAM system 150 is positioned as an extension 176 of accelerator 114 outside of the energy filter 118. Such a configuration illustrated in FIG. 1B, for example, can comprise turning off the energy filter 118 to allow a straight travel of the accelerated ion beam 116 out of accelerator 114 to the BAM system 150 along the alternate beam path 156.

The present disclosure contemplates various implementations of the BAM system 150. In a first example, the measured beam angle (e.g., the entrance angle offset Θ of FIGS. 4A-4B) at the exit of accelerator 114 allows for a re-tuning of the accelerator and various upstream component(s) such as the mass analyzer 110, to provide a zero beam angle. Such a re-tuning can be a serial process of repeated cycles of angle measurements and tuning. In a second example, as described above, once the measured beam angle is determined to be non-zero, an energy readout of the energy filter 118 of FIG. 1 can be corrected according to the formula provided in equation (1), above. For example, in the XE High Energy Implanter example provided above in equation (2), once the entrance beam angle is found to be −0.48 deg, dE=2%, which indicates that the accelerated ion beam 116 passing through the ERS 138 is 2% above the set value of the energy filter 118, and any of the various corrections discussed above may be implemented. For example, the controller 148 can be configured to determine the beam energy of the accelerated ion beam 116 based on the energy filter formula described above. The controller 148, for example, can be further configured to determine, control, and/or modify the one or more beam parameters associated with the energy filter formula discussed above based on the measurement 170 from the BAM system 150. The various corrections can be further implemented via the controller 148, or the corrections may be performed manually by an operator.

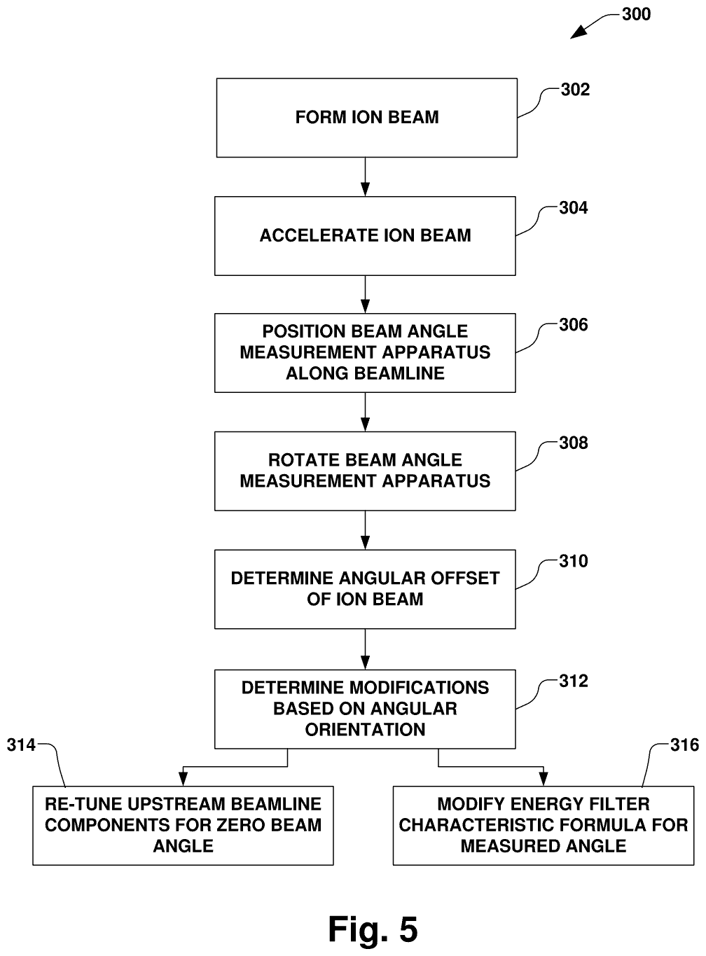

In accordance with yet another exemplary aspect, a method 300 for profiling an ion beam is illustrated in FIG. 5. It should be noted that while exemplary methods are illustrated and described herein as a series of acts or events, it will be appreciated that the present invention is not limited by the illustrated ordering of such acts or events, as some steps may occur in different orders and/or concurrently with other steps apart from that shown and described herein, in accordance with the invention. In addition, not all illustrated steps may be required to implement a methodology in accordance with the present invention. Moreover, it will be appreciated that the methods may be implemented in association with the systems illustrated and described herein as well as in association with other systems not illustrated.

As illustrated in FIG. 5, in accordance with one example, the method 300 comprises forming a high energy ion beam in act 302. The high energy ion beam is accelerated in act 304, and a final energy spectrum of the ion beam is attained in act 306. In act 308, a beam angle measurement apparatus is positioned with respect to a path of the high energy ion beam. The beam angle measurement apparatus, for example, may be selectively positioned along the path of the ion beam in act 308, or the path of the ion beam may be controlled by selectively deactivating one or more components such that the path coincides with a position of the beam angle measurement apparatus.

A beam angle offset of the ion beam at the final energy spectrum is determined in act 310. Based on the beam angle offset determined in act 310, one or more modifications or corrections are determined in act 312. The one or more modifications determined in act 312, for example, may comprise re-tuning of upstream beamline components in act 314, such as controlling the acceleration of act 304 by modifying parameters associated with the accelerator 114 of FIGS. 1A-1B discussed above. Alternatively, or in addition, the determination of modifications performed in act 314 of FIG. 5 may comprise a control of an angular energy filter in act 316. In another alternative, act 312 may comprise determining a modification of a read-out or display of the beam energy can be modified from the energy filter setting using the equation (1) for the offsets provided above in act 310.

Although the invention has been shown and described with respect to one or more implementations, equivalent alterations and modifications will occur to others skilled in the art based upon a reading and understanding of this specification and the annexed drawings. The invention includes all such modifications and alterations and is limited only by the scope of the following claims. In particular regard to the various functions performed by the above described components (assemblies, devices, circuits, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “includes”, “having”, “has”, “with”, or variants thereof are used in either the detailed description or the claims, such terms are intended to be inclusive in a manner similar to the term “comprising.” Also, the term “exemplary” as utilized herein simply means example.

What is claimed is:

1. An ion implantation system, comprising:
an ion source configured to form an ion beam along a reference beam path;
an accelerator positioned downstream of the ion source and configured to accelerate the ion beam to produce an accelerated ion beam having a predetermined energy;
an energy filter positioned downstream of the accelerator and configured to accept the accelerated ion beam at an entrance thereof;
a beam measurement device positioned downstream of the accelerator and configured to determine an angular orientation of the accelerated ion beam with respect to the entrance of the energy filter; and
a controller configured to control one or more of the accelerator and the energy filter based on the determined angular orientation of the accelerated ion beam.

2. The ion implantation system of claim 1, wherein the beam measurement device is selectively positioned between the accelerator and the energy filter along the reference beam path.

3. The ion implantation system of claim 2, wherein the beam measurement device is configured to translate and/or rotate with respect to the reference beam path.

4. The ion implantation system of claim 1, wherein the beam measurement device is positioned along an alternate beam path downstream of the accelerator such that the beam measurement device receives the accelerated ion beam along the alternate beam path by selective deactivation of the energy filter.

5. The ion implantation system of claim 1, wherein the beam measurement device is configured to determine an angular offset of the accelerated ion beam as the accelerated ion beam enters the energy filter, the beam measurement device further comprising:
a faraday;
a mask having a plurality of tines that generally define a plurality of slits, the mask positioned upstream of the faraday; and
an encoder operably coupled to the mask.

6. The ion implantation system of claim 5, wherein the mask comprises graphite.

7. The ion implantation system of claim 1, wherein the beam measurement device selectively positioned along an exit axis of the accelerator and proximate to the energy filter.

8. The ion implantation system of claim 1, wherein the controller is further configured to control the accelerator based on the determined angular orientation of the accelerated ion beam to obtain a beam angle of approximately zero at the entrance of the energy filter.

9. The ion implantation system of claim 1, wherein the controller is further configured to control one or more beam parameters of an energy filter formula based on the determined angular orientation of the ion beam, wherein the energy filter formula is based on a characterization of the energy filter.

10. An ion implantation system, comprising:
an ion source configured to form an ion beam along a reference beam path;
an RF linear accelerator positioned downstream of the ion source and configured to accelerate the ion beam to produce an accelerated ion beam having a predetermined energy along an exit axis of the RF linear accelerator;
a magnetic energy filter positioned downstream of the RF linear accelerator and configured to accept the accelerated ion beam at an entrance thereof;
a beam measurement device positioned downstream of the RF linear accelerator, wherein the beam measurement device comprises a mask positioned upstream of a faraday and is configured to determine an angular orientation of the accelerated ion beam with respect to the entrance of the magnetic energy filter based, at least in part, on current of the ion beam passing through the mask and reaching the faraday; and
a controller configured to control one or more beam parameters associated with the RF linear accelerator and magnetic energy filter based on the determined angular orientation of the ion beam, wherein the one or more beam parameters are further associated with an energy filter formula and a characterization of the magnetic energy filter.

11. The ion implantation system of claim 10, wherein the angular orientation of the accelerated ion beam with respect to the entrance of the magnetic energy filter is further based a position of the beam measurement device with respect to the reference beam path.

12. The ion implantation system of claim 10, wherein the magnetic energy filter comprises an electromagnet.

13. The ion implantation system of claim 12, wherein the controller is configured to direct the accelerated ion beam along an alternate beam path by selectively deactivating the magnetic energy filter.

14. The ion implantation system of claim 13, wherein the beam measurement device is positioned along the alternate beam path.

15. The ion implantation system of claim 10, wherein the mask further comprises a plurality of tines that generally define a plurality of slits.

16. The ion implantation system of claim 15, wherein the beam measurement device further comprises an encoder operably coupled to the mask.

17. The ion implantation system of claim 15, wherein the mask comprises graphite.

18. A method of profiling and modifying an ion beam, the method comprising:
forming, with an ion source, the ion beam along a reference beam path;
accelerating the ion beam with an accelerator positioned downstream of the ion source to produce an accelerated ion beam having a predetermined energy;
determining, with a beam measurement device positioned downstream of the accelerator, an angular orientation of the accelerated ion beam with respect to an entrance of an energy filter positioned downstream of the accelerator; and
configuring, with a controller, one or more of the accelerator and the energy filter based on the determined angular orientation of the accelerated ion beam.

19. The method of claim 18, further comprising:
selectively positioning the beam measurement device between the accelerator and the energy filter along the reference beam path; and
translating and/or rotating the beam measurement device with respect to the reference beam path to determine the angular orientation of the accelerated ion beam.

20. The method of claim 18, further comprising:
selectively deactivating the energy filter so as to direct the accelerated ion beam along an alternate beam path downstream of the accelerator such that the beam measurement device receives the accelerated ion beam.
